(19) United States
(12) Patent Application Publication
(10) Pub. No.: US 2012/0110354 A1
(43) Pub. Date: May 3, 2012

(54) HOLDER WITH SOLAR MODULE FOR HOLDING PORTABLE ELECTRONIC DEVICES

(75) Inventor: YUNG-LUNG LIU, Ta Ya Shiang (TW)

(73) Assignee: Sunrex Technology Corp., Ta Ya Shiang (TW)

(21) Appl. No.: 12/917,797

(22) Filed: Nov. 2, 2010

(51) Int. Cl. H05K 7/14; G06F 1/26

(52) U.S. Cl. 713/300; 248/291.1

(57) ABSTRACT

One embodiment of a holder for holding portable electronic devices includes a main support body being a rectangular rigid plate; a main support member hingedly secured to a rear end of the main support body, the main support member being a rectangular rigid plate and comprising two spaced hinge housings proximate to a top edge distal the main support body; and two parallel support legs hingedly secured to a back of the main support member; and a rectangular solar panel comprising two pivots at two top corners respectively, each pivot pivotably secured to the hinge housing so that an angle of the solar panel with respect to the main support member can be adjusted for orienting toward the sun.

### BACKGROUND OF THE INVENTION

1. Field of Invention The invention relates to holding devices and more particularly to a holder with a solar module for not only securely holding one or two portable electronic devices but also supplying solar energy converted electricity thereto.

2. Description of Related Art

A wide variety of electronic products are commercially available due to the advancement of science and technology. One important feature of these products is that they are portable. Such portable electronic devices include, but not limited to, cellular phones, PDAs (personal digital assistants), palm type game machines, and tablet computers. Moreover, for laptops its keyboard is thin and may incorporate a touch pad or a trackball. These portable electronic devices may be actuated by wire (e.g., USB (universal serial bus)) or wireless (e.g., RF (radio frequency) or Bluetooth) technology.

These portable electronic devices are relatively expensive and advanced products. Thus, how to protect them in transport or use is an important issue. There are many different types of product for protecting portable electronic devices are available in the market. However, such products are disadvantageous because they are inferior in quality, not durable, awkward to carry, inconvenience in use, etc.

Another problem with portable electronic devices is that battery for supplying electricity to the portable electronic device (e.g., laptop computer) is limited in capacity. It is possible that battery of the laptop computer is consumed when a user is using the laptop computer. The user thus has to stop using the laptop computer and charge the battery. Unfortunately, the charging may take several hours. This can bring inconvenience in use especially in an outdoor environment. Thus, the need for improvement still exists.

### SUMMARY OF THE INVENTION

It is therefore one object of the invention to provide a holder for holding portable electronic devices comprising a main support body being a rectangular rigid plate; a main support member hingedly secured to a rear end of the main support body, the main support member being a rectangular rigid plate and comprising two spaced hinge housings proximate to a top edge distal the main support body; and support means hingedly secured to a back of the main support member; and a rectangular solar panel comprising two pivots at two top corners respectively, each pivot pivotably secured to the hinge housing so that an angle of the solar panel with respect to the main support member can be adjusted for orienting toward the sun.

It is another object of the invention to provide a holder for holding portable electronic devices comprising a main support body being a rectangular rigid plate and comprising an upwardly extending closed, rectangular, flexible flange on a top surface for retaining an electronic input device therein; a main support member hingedly secured to a rear end of the main support body, the main support member being a rectangular rigid plate and comprising an extending closed, rectangular, flexible flange on a front surface for retaining an electronic processing device therein and a top pipe shaped hinge having an opening; support means hingedly secured to a back of the main support member; and a spool of solar module adapted to roll into the pipe shaped hinge or extend therefrom.

The above and other objects, features and advantages of the invention will become apparent from the following detailed description taken with the accompanying drawings.

### BRIEF DESCRIPTION OF THE DRAWINGS

FIG. 1 is an exploded perspective view of a holder with a solar panel according to a first preferred embodiment of the invention, two portable electronic devices to be held thereon;

FIG. 2 is a longitudinal sectional view of the assembled holder with both the electronic input device and the electronic processing device being held thereon and the solar panel being retracted;

FIG. 3 is a view similar to FIG. 2 showing the solar panel being extended for use;

FIG. 4 is a rear view of FIG. 2;

FIG. 5 is a top plan view of FIG. 3 showing the extended solar panel;

FIG. 6 is a block diagram of the solar panel, the controller, the battery, and the electronic processing device;

FIG. 7 is a detailed block diagram of FIG. 6;

FIG. 8 is an exploded perspective view of a holder with a spool of solar module according to a second preferred embodiment of the invention, two portable electronic devices to be held thereon;

FIG. 9 is a longitudinal sectional view of the assembled holder of FIG. 8 with both the electronic input device and the electronic processing device being held thereon and the spool of solar module being retracted; and

FIG. 10 is a view similar to FIG. 9 showing the spool of solar module being extended for use.

### DETAILED DESCRIPTION OF THE INVENTION

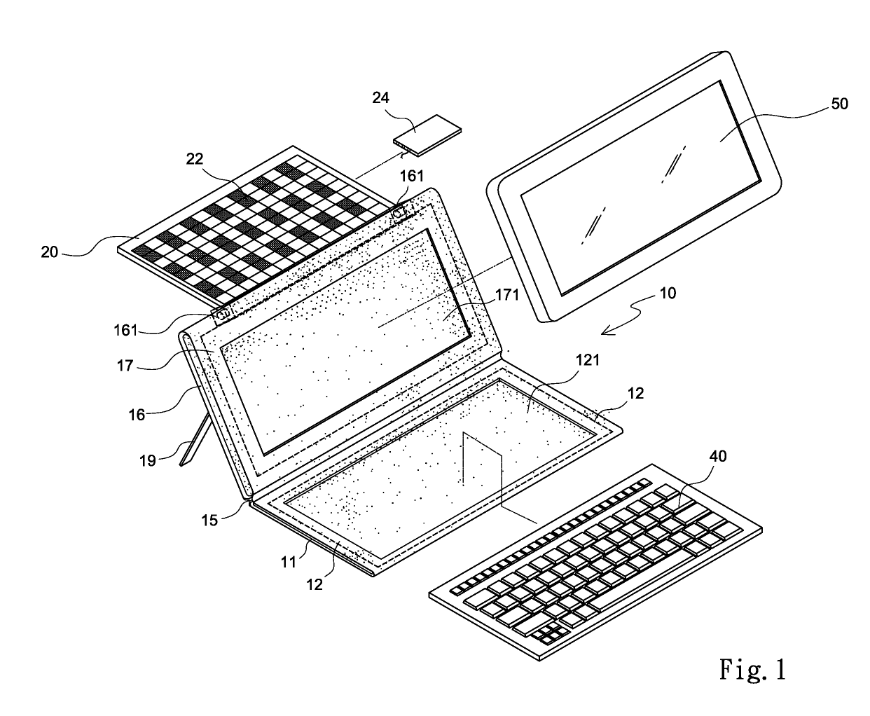

Referring to FIGS. 1 to 7, a holder 10 for holding portable electronic devices in accordance with a first preferred embodiment of the invention comprises a main support body 11, a main support member 16, two parallel support legs 19, and a solar panel 20 as discussed in detail below.

The main support body 11 is a rectangular rigid plate. The main support body 11 has an upwardly extending closed, rectangular, flexible flange 12. A rectangular recess 121 is defined by the flange 12. The flange 12 is made of elastomeric material so that an electronic input device 40 may be retained in the recess 121. The electronic input device 40 can be a thin keyboard incorporating a touch pad or a trackball. A flexible hinge 15 is provided on a rear edge of the main support body 11. A main support member 16 extends outward from the hinge 15 so that the main support member 16 may be closed onto the main support body 11 or open with respect to the main support body 11 by pivoting about the hinge 15.

The main support member 16 is a rectangular rigid plate. Back of the main support member 16 comprises two spaced hinge housings 161 proximate to the top edge distal the hinge 15 and front surface thereof comprises an extending, closed, rectangular, flexible flange 17. A rectangular recess 171 is defined by the flange 17. The flange 17 is made of elastomeric material so that an electronic processing device 50 may be retained in the recess 171. The electronic processing device 50 can be a cellular phone, a PDA, or a tablet computer. Note that the electronic input device 40 and the electronic processing device 50 can be communicated by wire or wireless.

Each support leg 19 is a rod-like member and is disposed proximate to the side. The support leg 19 comprises a pivot 191 at a top end pivotably secured to the back of the main support member 16, and a bottom end 192 rested upon a planar surface (e.g., desk top). This arrangement enables a user to comfortably view the electronic processing device 50 in an optimum tilt angle.

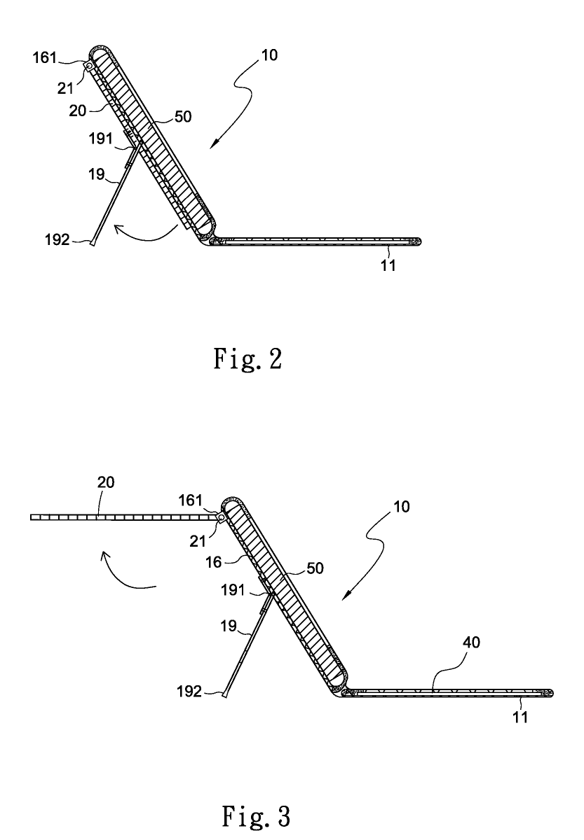

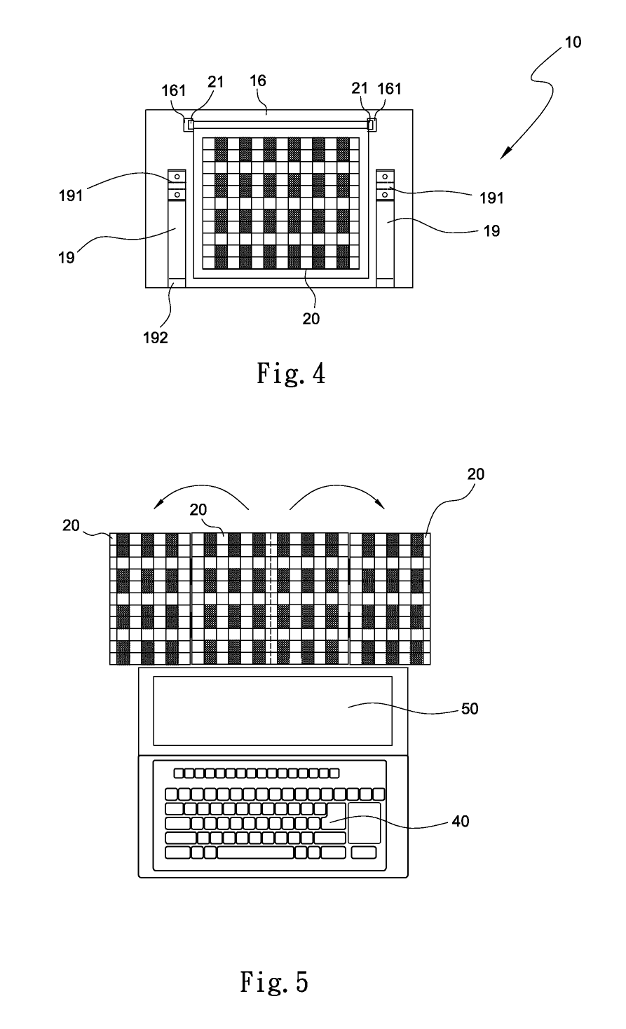

The solar panel 20 is a rectangular plate having a frame. The solar panel 20 comprises two pivots 21 at two top corners respectively (see FIG. 4). Each pivot 21 is pivotably secured to the hinge housing 161 so that the pivotal solar panel 20 may be either retracted onto the back of the main support member 16 in an inoperative position (see FIG. 2) or extended to be, for example, disposed horizontally in an operating position (see FIG. 3). It is note that an angle of the solar panel 20 with respect to the main support member 16 can be adjusted so that the solar panel 20 may be adjustably, appropriately oriented toward the sun for collecting maximum energy from the sunlight. It is further noted that the pivotal connections of the pivots 21 and the hinge housings 16 are relatively tight after being adjusted. Moreover, the solar panel 20 is lightweight. Thus a user does not need to worry the tilt angle adjusted solar panel 20 may undesirably pivot counterclockwise toward the back of the main support member 16 in use.

The solar panel 20 further comprises a plurality of solar cells 22 being packaged and interconnected as an assembly. The solar cells 22 are made from monocrystalline silicon wafer and are capable of converting the energy of sunlight directly into electricity by the photovoltaic effect. A glass (not shown) may be mounted on the front surface of the solar panel 20 for protecting the solar cells 22.

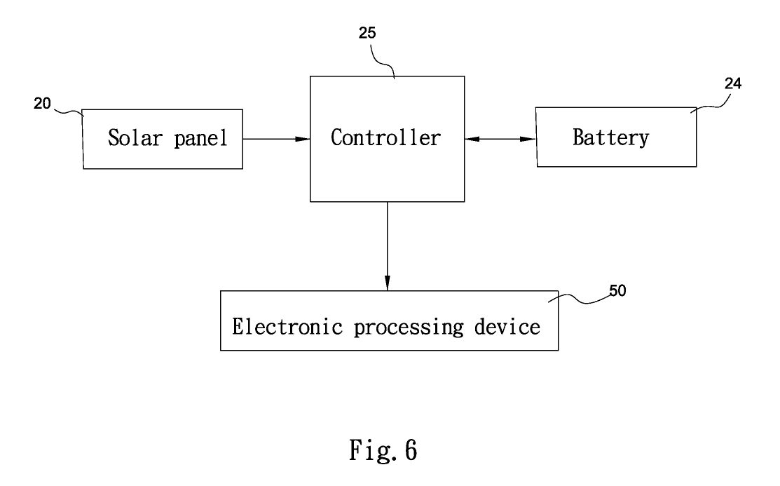

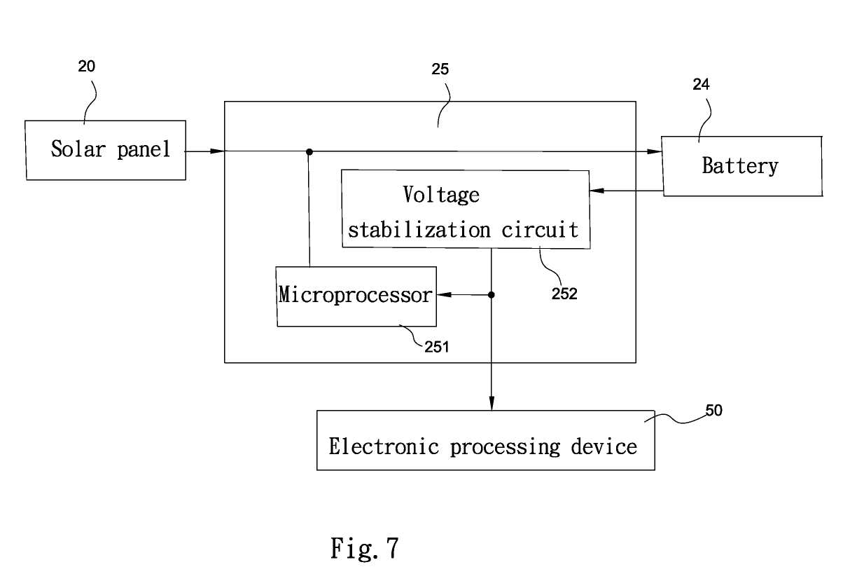

As shown in FIGS. 6 and 7, the solar panel 20 is electrically connected to an internal controller 25. Further, the electronic processing device 50 is releasably electrically connected to the controller 25. An external rechargeable battery 24 is releasably electrically connected to the controller 25. The battery 24 can store an electrical charge from the solar cells 22 via the controller 25 and supply electricity to, for example, the electronic processing device 50 via the controller 25.

The controller 25 comprises a microprocessor 251 electrically interconnecting the solar panel 20 and the battery 24 for measuring the remaining amount of electricity stored in the battery 24. The microprocessor 251 can stop charging of the battery 24 if the battery 24 is full. The controller 25 further comprises a voltage stabilization circuit 252 electrically interconnecting the electronic processing device 50 and the battery 24 for regulating power supplied to the electronic processing device 50 within a predetermined range so that the electronic processing device 50 may be operated normally.

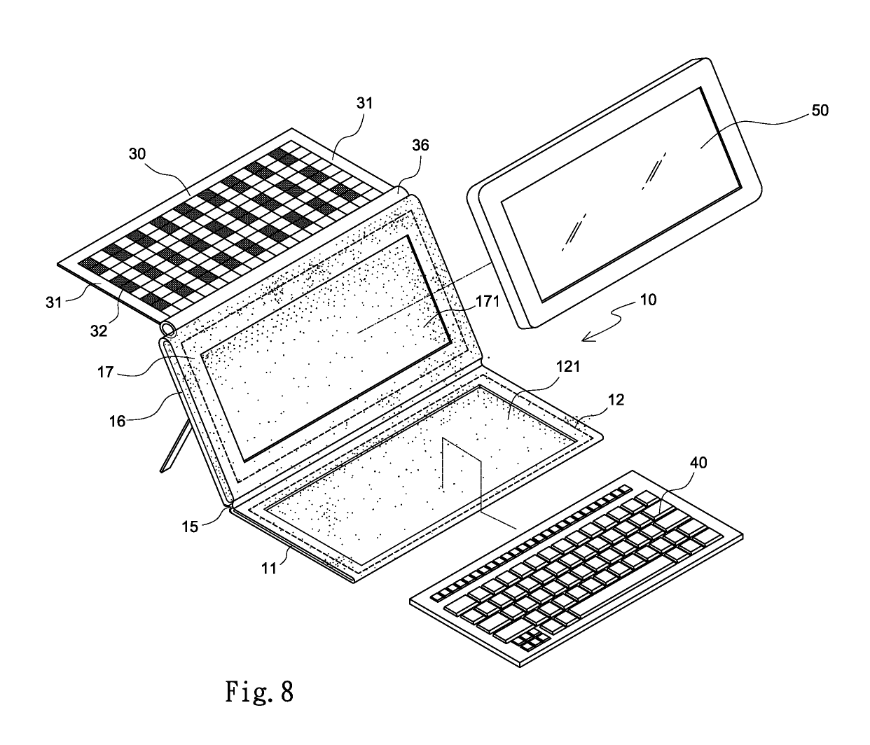

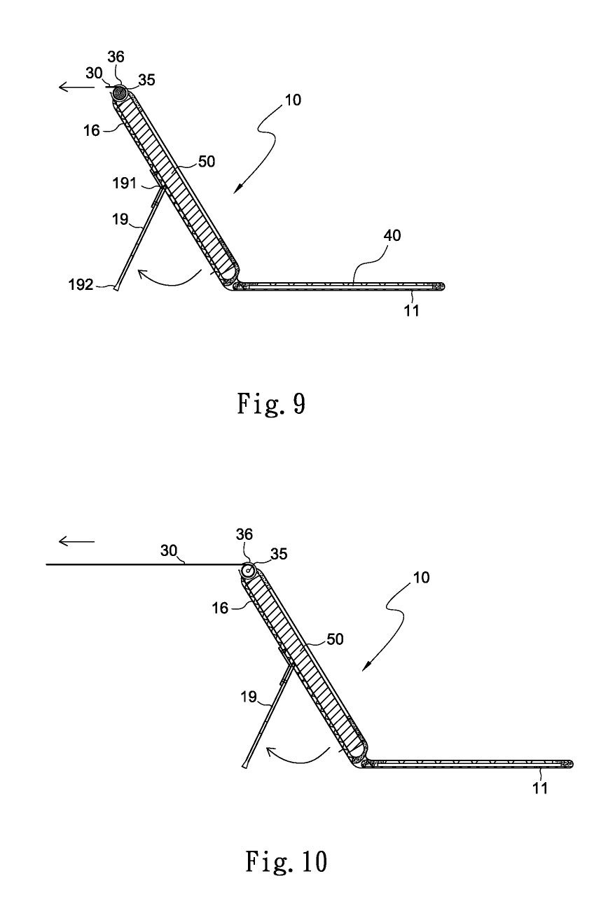

Referring to FIGS. 8 to 10, a holder 10 for holding portable electronic devices in accordance with a second preferred embodiment of the invention is shown. The characteristics of the second preferred embodiment are substantially the same as that of the first preferred embodiment except the following:

The plate shaped solar panel is replaced with a spool of solar module 30 functioning similar to a roll film. The spool of solar module 30 can be rolled into a pipe shaped hinge 36 having an opening formed on a top edge of the main support member 16 in an inoperative position for saving storage space. Alternatively, the spool of solar module 30 can be rolled out of the pipe shaped hinge 36 to be shaped as a plate in an operating position. The solar energy collected by the extended spool of solar module 30 is directly proportional to the area of the spool of solar module 30 rolled out of the pipe shaped hinge 36. Also, the spool of solar module 30 is locked after the hand pulling the spool of solar module 30 releases. After use, the user may pull the spool of solar module 30 slightly and then release same so that the spool of solar module 30 can automatically roll into the pipe shaped hinge 36. Alternatively, the spool of solar module 30 can be rolled into the pipe shaped hinge 36 manually. Both retracting methods are well known in the art.

The spool of solar module 30 further comprises a flexible frame 31 shaped as a U and a plurality of solar cells 32 being packaged and interconnected as an assembly. The solar cells 32 are made from monocrystalline silicon wafer and are capable of converting the energy of sunlight directly into electricity by the photovoltaic effect. A glass (not shown) may be mounted on the front surface of the spool of solar module 30 for protecting the solar cells 32.

While the invention has been described in terms of preferred embodiments, those skilled in the art will recognize that the invention can be practiced with modifications within the spirit and scope of the appended claims.

What is claimed is:

1. A holder for holding portable electronic devices comprising:
a main support body being a rectangular rigid plate;
a main support member hingedly secured to a rear end of the main support body, the main support member being a rectangular rigid plate and comprising two spaced hinge housings proximate to a top edge distal the main support body;
support means hingedly secured to a back of the main support member; and
a rectangular solar panel comprising two pivots at two top corners respectively, each pivot pivotably secured to the hinge housing so that an angle of the solar panel with respect to the main support member can be adjusted for orienting toward the sun.

2. The holder of claim 1, wherein the main support body comprises an upwardly extending closed, rectangular, flexible flange on a top surface, the flange of the main support body defining a rectangular recess for retaining an electronic input device which is a thin keyboard incorporating a touch pad or a trackball; wherein the main support member comprises an extending closed, rectangular, flexible flange on a front surface, the flange of the main support member defining a rectangular recess for retaining an electronic processing device which is a cellular phone, a PDA, or a tablet computer; and wherein the electronic input device and the electronic processing device can be communicated by wire or wireless.

3. The holder of claim 1, wherein the solar panel can be either retracted onto the back of the main support member in an inoperative position or extended in an operating position.

4. The holder of claim 1, wherein the solar panel further comprises a plurality of solar cells packaged and interconnected, the solar cells being made from monocrystalline silicon wafer.

5. The holder of claim 2, further comprising a controller electrically connected to the solar panel, the controller being releasably electrically connected to the electronic processing device, and an external rechargeable battery releasably electrically connected to the controller, the battery being capable of storing an electrical charge from the solar cells via the controller and supplying electricity to the electronic processing device via the controller.

6. The holder of claim 5, wherein the controller comprises a microprocessor electrically interconnecting the solar panel and the battery for measuring remaining amount of electricity stored in the battery, and a voltage stabilization circuit electrically interconnecting the electronic processing device and the battery for regulating power supplied to the electronic processing device within a predetermined range.

7. A holder for holding portable electronic devices comprising:
a main support body being a rectangular rigid plate and comprising an upwardly extending closed, rectangular, flexible flange on a top surface for retaining an electronic input device therein;
a main support member hingedly secured to a rear end of the main support body, the main support member being a rectangular rigid plate and comprising an extending closed, rectangular, flexible flange on a front surface for retaining an electronic processing device therein and a top pipe shaped hinge having an opening;
support means hingedly secured to a back of the main support member; and
a spool of solar module adapted to roll into the pipe shaped hinge or extend therefrom.

8. The holder of claim 7, wherein the spool of solar module comprises a flexible U-shaped frame so that the spool of solar module can be rolled out of the pipe shaped hinge as a panel in an operating position.

9. The holder of claim 7, wherein the spool of solar module further comprises a plurality of solar cells packaged and interconnected, the solar cells being made from monocrystalline silicon wafer.

10. The holder of claim 9, further comprising a controller electrically connected to the spool of solar module, the controller being releasably electrically connected to the electronic processing device, and an external rechargeable battery releasably electrically connected to the controller, the battery being capable of storing an electrical charge from the solar cells via the controller and supplying electricity to the electronic processing device via the controller; and wherein the controller comprises a microprocessor electrically interconnecting the solar panel and the battery for measuring remaining amount of electricity stored in the battery, and a voltage stabilization circuit electrically interconnecting the electronic processing device and the battery for regulating power supplied to the electronic processing device within a predetermined range.
